(19) United States
(12) Patent Application Publication
(10) Pub. No.: US 2021/0135474 A1
(43) Pub. Date: May 6, 2021

(54) MOBILE TERMINAL AND CONTROL METHOD THEREOF

(71) Applicant: LG ELECTRONICS INC., Seoul (KR)

(72) Inventors: Minhun HA, Seoul (KR); Hyeongseog KIM, Seoul (KR); Sanghoon KIM, Seoul (KR); Chansin PARK, Seoul (KR); Buyoung YANG, Seoul (KR); Junhyeong WOO, Seoul (KR)

(73) Assignee: LG ELECTRONICS INC., Seoul (KR)

(21) Appl. No.: 16/972,297

(22) PCT Filed: Jul. 13, 2018
(86) PCT No.: PCT/KR2018/007972

§ 371 Date: Dec. 4, 2020

(51) Int. Cl. H02J 7/00

(52) U.S. Cl. CPC H02J 7/00712; H02J 7/0048

(57) ABSTRACT

Provided is a mobile terminal (electronic device) which, in order to minimize aging of a battery included therein through repeated charging/discharging, comprises: the battery charged by a voltage applied thereto; a monitoring device for monitoring a charging condition of the battery, and a charging frequency of the battery; a battery charger for adjusting the voltage applied to the battery; and a controller for controlling the battery, the monitoring device, and the battery charger, wherein, when the battery is charged in a pre-configured charging condition, the controller controls the monitoring device to adjust the charging frequency in response to the pre-configured charging condition, and controls the battery charger to apply a voltage corresponding to the adjusted charging frequency to the battery.

### TECHNICAL FIELD

The present disclosure relates to a mobile terminal and control method thereof. More particularly, the present disclosure pertains to the field of preventing a battery included in a mobile terminal from aging.

### BACKGROUND ART

Terminals may be generally classified as mobile/portable terminals or stationary terminals according to their mobility. Mobile terminals may also be classified as handheld terminals or vehicle mounted terminals according to whether or not a user can directly carry the terminal.

Mobile terminals have become increasingly more functional. Examples of such functions include data and voice communications, capturing images and video via a camera, recording audio, playing music files via a speaker system, and displaying images and video on a display. Some mobile terminals include additional functionality which supports game playing, while other terminals are configured as multimedia players. More recently, mobile terminals have been configured to receive broadcast and multicast signals which permit viewing of content such as videos and television programs.

As such functions become more diversified, the mobile terminal can support more complicated functions such as capturing images or video, reproducing music or video files, playing games, receiving broadcast signals, and the like. By comprehensively and collectively implementing such functions, the mobile terminal may be embodied in the form of a multimedia player or device.

Efforts are ongoing to support and increase the functionality of mobile terminals. Such efforts include software and hardware improvements, as well as changes and improvements in the structural components.

In recent years, mobile terminals with various functionality such as smartphones have been widely provided. A sufficient battery capacity is required to support various functions. However, as the number of uses based on charge and discharge increases, the battery capacity decreases due to degradation. Accordingly, battery anti-aging for minimizing the battery degradation even though the number of uses increases has been researched.

### DISCLOSURE

### Technical Problem

The object of the present disclosure is to solve the above-described problems and other problems, which will be described in this document.

The present disclosure is to provide a solution for preventing battery aging by weighting the number of battery charge cycles based on factors that affect battery degradation when a charge voltage varies depending on the number of battery charge cycles.

The present disclosure is to provide a solution for preventing battery aging by weighting the number of battery charge cycles based on a battery charge temperature (high temperature) and a duration thereof when a charge voltage varies depending on the number of battery charge cycles.

The present disclosure is to provide a solution for preventing battery aging by weighting the number of battery charge cycles based on a battery charge voltage (high voltage) and a duration thereof when a charge voltage varies depending on the number of battery charge cycles.

The present disclosure is to provide a solution for preventing battery aging by reducing a current in a constant-current charge period based on the number of battery charge cycles when a charge voltage varies depending on the number of battery charge cycles.

### Technical Solution

In one aspect of the present disclosure, an electronic device is provided. The electronic device may include a battery configured to be charged when a voltage is applied, a monitoring device configured to monitor a charge condition of the battery and a number of charge cycles of the battery, a battery charger configured to adjust the voltage applied to the battery, and a controller configured to control the battery, the monitoring device, and the battery charger. The controller may be configured to, when the battery is charged with a predetermined charge condition, control the monitoring device to adjust the number of charge cycles based on the predetermined charge condition, and control the battery charger to apply a voltage based on the adjusted number of charge cycles to the battery.

In another aspect of the present disclosure, a method of controlling an electronic device is provided. The method may include monitoring a charge condition of a battery included in the electronic device and a number of charge cycles of the battery, when the charge condition of the battery corresponds to a predetermined charge condition, adjusting the number of charge cycles based on the predetermined charge condition, and adjusting a charge voltage applied to the battery based on the adjusted number of charge cycles.

### Advantageous Effects

According to the present disclosure, the mobile terminal and control method thereof may have the following effects.

According to the present disclosure, a solution for preventing battery aging by reflecting factors that affect battery degradation in the number of battery charge cycles when a battery charge voltage is adjusted depending on the number of battery charge cycles is provided.

According to the present disclosure, a solution for preventing battery aging by weighting the number of battery charge cycles based on a battery charge temperature (high temperature) and a duration thereof when a battery charge voltage is adjusted depending on the number of battery charge cycles is provided.

According to the present disclosure, a solution for preventing battery aging by weighting the number of battery charge cycles based on a battery charge voltage (high voltage) and a duration thereof when a battery charge voltage is adjusted depending on the number of battery charge cycles is provided.

According to the present disclosure, a solution for preventing battery aging by reducing a current in a constant-current charge period based on the number of battery charge cycles when a battery charge voltage is adjusted depending on the number of battery charge cycles is provided.

### DESCRIPTION OF DRAWINGS

FIG. 1A is a block diagram for explaining a mobile terminal according to an embodiment of the present disclosure.

FIGS. 1B and 1C are conceptual views illustrating one example of a mobile terminal, viewed from different directions.

FIG. 2 is a block diagram illustrating major component blocks of an electronic device according to an embodiment of the present disclosure.

FIG. 3 is a graph showing one charge cycle of the battery included in the electronic device according to an embodiment of the present disclosure.

FIG. 4 is a flowchart for explaining an algorithm for preventing the aging of the battery included in the electronic device according to an embodiment of the present disclosure.

FIG. 5 is a table showing factors (e.g., high temperature, high voltage, etc.) that affect the battery aging in the electronic device according to an embodiment of the present disclosure.

FIG. 6 is a graph showing the table of FIG. 5.

FIG. 7 is a graph showing a range in which factors that affect the battery aging are weighted in the electronic device according to an embodiment of the present disclosure.

FIG. 8 is a graph showing the weight values of FIG. 7.

FIG. 9 is a graph showing a factor (constant current) that affects the battery aging in the electronic device according to an embodiment of the present disclosure.

FIG. 10 is a table showing a charge algorithm for preventing the battery again in the electronic device according to an embodiment of the present disclosure.

FIG. 11 is a graph showing the charge algorithm for preventing the battery again in the electronic device according to an embodiment of the present disclosure.

### BEST MODE

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

Mobile terminals presented herein may be implemented using a variety of different types of terminals. Examples of such terminals include cellular phones, smart phones, user equipment, laptop computers, digital broadcast terminals, personal digital assistants (PDAs), portable multimedia players (PMPs), navigators, portable computers (PCs), slate PCs, tablet PCs, ultra-books, wearable devices (for example, smart watches, smart glasses, head mounted displays (HMDs)), and the like.

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, and the like.

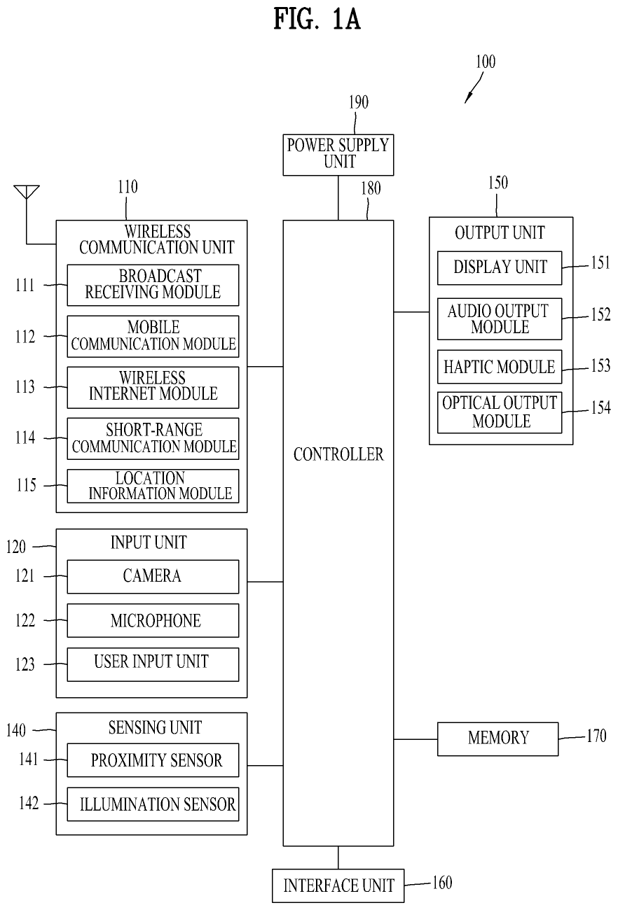

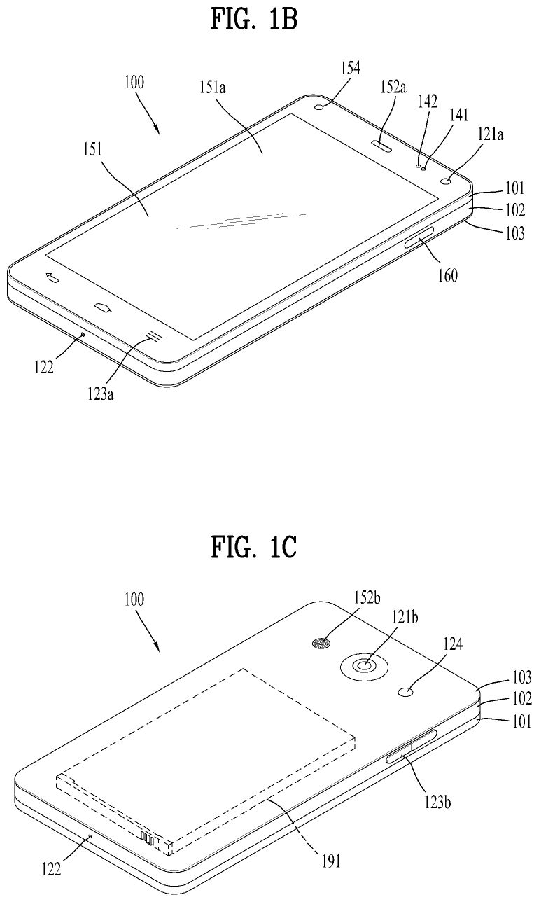

Reference is now made to FIGS. 1A-1C, where FIG. 1A is a block diagram of a mobile terminal in accordance with the present disclosure.

FIGS. 1B and 1C are conceptual views of one example of the mobile terminal, viewed from different directions.

The mobile terminal 100 is shown having components such as a wireless communication unit 110, an input unit 120, a sensing unit 140, an output unit 150, an interface unit 160, a memory 170, a controller 180, and a power supply unit 190. It is understood that implementing all of the illustrated components is not a requirement, and that greater or fewer components may alternatively be implemented

Referring now to FIG. 1A, the mobile terminal 100 is shown having wireless communication unit 110 configured with several commonly implemented components. For instance, the wireless communication unit 110 typically includes one or more components which permit wireless communication between the mobile terminal 100 and a wireless communication system or network within which the mobile terminal is located.

To facilitate such communications, the wireless communication unit 110 includes one or more of a broadcast receiving module 111, a mobile communication module 112, a wireless Internet module 113, a short-range communication module 114, and a location information module 115.

The input unit 120 includes a camera 121 for obtaining images or video, a microphone 122, which is one type of audio input device for inputting an audio signal, and a user input unit 123 (for example, a touch key, a push key, a mechanical key, a soft key, and the like) for allowing a user to input information. Data (for example, audio, video, image, and the like) is obtained by the input unit 120 and may be analyzed and processed by controller 180 according to device parameters, user commands, and combinations thereof.

The sensing unit 140 is typically implemented using one or more sensors configured to sense internal information of the mobile terminal, the surrounding environment of the mobile terminal, user information, and the like. For example, in FIG. 1A, the sensing unit 140 is shown having a proximity sensor 141 and an illumination sensor 142. If desired, the sensing unit 140 may alternatively or additionally include other types of sensors or devices, such as a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 121), a microphone 122, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like), to name a few. The mobile terminal 100 may be configured to utilize information obtained from sensing unit 140, and in particular, information obtained from one or more sensors of the sensing unit 140, and combinations thereof.

The output unit 150 is typically configured to output various types of information, such as audio, video, tactile output, and the like. The output unit 150 is shown having a display unit 151, an audio output module 152, a haptic module 153, and an optical output module 154. The display unit 151 may have an inter-layered structure or an integrated structure with a touch sensor in order to facilitate a touch screen. The touch screen may provide an output interface between the mobile terminal 100 and a user, as well as function as the user input unit 123 which provides an input interface between the mobile terminal 100 and the user.

The interface unit 160 serves as an interface with various types of external devices that can be coupled to the mobile terminal 100. The interface unit 160, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the mobile terminal 100 may perform assorted control functions associated with a connected external device, in response to the external device being connected to the interface unit 160.

The memory 170 is typically implemented to store data to support various functions or features of the mobile terminal 100. For instance, the memory 170 may be configured to store application programs executed in the mobile terminal 100, data or instructions for operations of the mobile terminal 100, and the like. Some of these application programs may be downloaded from an external server via wireless communication. Other application programs may be installed within the mobile terminal 100 at time of manufacturing or shipping, which is typically the case for basic functions of the mobile terminal 100 (for example, receiving a call, placing a call, receiving a message, sending a message, and the like). It is common for application programs to be stored in the memory 170, installed in the mobile terminal 100, and executed by the controller 180 to perform an operation (or function) for the mobile terminal 100.

The controller 180 typically functions to control overall operation of the mobile terminal 100, in addition to the operations associated with the application programs. The controller 180 may provide or process information or functions appropriate for a user by processing signals, data, information and the like, which are input or output by the various components depicted in FIG. 1A, or activating application programs stored in the memory 170.

As one example, the controller 180 controls some or all of the components illustrated in FIGS. 1A-1C according to the execution of an application program that have been stored in the memory 170.

The power supply unit 190 can be configured to receive external power or provide internal power in order to supply appropriate power required for operating elements and components included in the mobile terminal 100. The power supply unit 190 may include a battery, and the battery may be configured to be embedded in the terminal body, or configured to be detachable from the terminal body.

At least some of the respective components may operate in cooperation with each other to implement the operation, control, or control method of the mobile terminal 100 according to various embodiments described below. In addition, the operation, control, or control method of the mobile terminal 100 may be implemented on the mobile terminal 100 by driving at least one application program stored in the memory 170.

The input unit 120 may be configured to permit various types of input to the mobile terminal 120. Examples of such input include audio, image, video, data, and user input. Image and video input is often obtained using one or more cameras 121.

The camera 121 may be a part of the mobile terminal 100 of the present disclosure, or may be a configuration including the mobile terminal 100. That is, the camera 121 and the mobile terminal 100 of the present disclosure may include at least some common features or configurations.

The cameras 121 may process image frames of still pictures or video obtained by image sensors in a video or image capture mode. The processed image frames can be displayed on the display unit 151 or stored in memory 170. In some cases, the cameras 121 may be arranged in a matrix configuration to permit a plurality of images having various angles or focal points to be input to the mobile terminal 100. As another example, the cameras 121 may be located in a stereoscopic arrangement to acquire left and right images for implementing a stereoscopic image.

The sensing unit 140 is generally configured to sense one or more of internal information of the mobile terminal, surrounding environment information of the mobile terminal, user information, or the like. The controller 180 generally cooperates with the sending unit 140 to control operation of the mobile terminal 100 or execute data processing, a function or an operation associated with an application program installed in the mobile terminal based on the sensing provided by the sensing unit 140. The sensing unit 140 may be implemented using any of a variety of sensors, some of which will now be described in more detail.

The proximity sensor 141 may include a sensor to sense presence or absence of an object approaching a surface, or an object located near a surface, by using an electromagnetic field, infrared rays, or the like without a mechanical contact. The proximity sensor 141 may be arranged at an inner region of the mobile terminal covered by the touch screen, or near the touch screen.

The proximity sensor 141, for example, may include any of a transmissive type photoelectric sensor, a direct reflective type photoelectric sensor, a mirror reflective type photoelectric sensor, a high-frequency oscillation proximity sensor, a capacitance type proximity sensor, a magnetic type proximity sensor, an infrared rays proximity sensor, and the like. When the touch screen is implemented as a capacitance type, the proximity sensor 141 can sense proximity of a pointer relative to the touch screen by changes of an electromagnetic field, which is responsive to an approach of an object with conductivity. In this case, the touch screen (touch sensor) may also be categorized as a proximity sensor.

The term “proximity touch” will often be referred to herein to denote the scenario in which a pointer is positioned to be proximate to the touch screen without contacting the touch screen. The term “contact touch” will often be referred to herein to denote the scenario in which a pointer makes physical contact with the touch screen. For the position corresponding to the proximity touch of the pointer relative to the touch screen, such position will correspond to a position where the pointer is perpendicular to the touch screen. The proximity sensor 141 may sense proximity touch, and proximity touch patterns (for example, distance, direction, speed, time, position, moving status, and the like). In general, controller 180 processes data corresponding to proximity touches and proximity touch patterns sensed by the proximity sensor 141, and cause output of visual information on the touch screen. In addition, the controller 180 can control the mobile terminal 100 to execute different operations or process different data according to whether a touch with respect to a point on the touch screen is either a proximity touch or a contact touch.

A touch sensor can sense a touch applied to the touch screen, such as display unit 151, using any of a variety of touch methods. Examples of such touch methods include a resistive type, a capacitive type, an infrared type, and a magnetic field type, among others.

As one example, the touch sensor may be configured to convert changes of pressure applied to a specific part of the display unit 151, or convert capacitance occurring at a specific part of the display unit 151, into electric input signals. The touch sensor may also be configured to sense not only a touched position and a touched area, but also touch pressure and/or touch capacitance. A touch object is generally used to apply a touch input to the touch sensor. Examples of typical touch objects include a finger, a touch pen, a stylus pen, a pointer, or the like.

When a touch input is sensed by a touch sensor, corresponding signals may be transmitted to a touch controller. The touch controller may process the received signals, and then transmit corresponding data to the controller 180. Accordingly, the controller 180 may sense which region of the display unit 151 has been touched. Here, the touch controller may be a component separate from the controller 180, the controller 180, and combinations thereof.

In some embodiments, the controller 180 may execute the same or different controls according to a type of touch object that touches the touch screen or a touch key provided in addition to the touch screen. Whether to execute the same or different control according to the object which provides a touch input may be decided based on a current operating state of the mobile terminal 100 or a currently executed application program, for example.

The touch sensor and the proximity sensor may be implemented individually, or in combination, to sense various types of touches. Such touches includes a short (or tap) touch, a long touch, a multi-touch, a drag touch, a flick touch, a pinch-in touch, a pinch-out touch, a swipe touch, a hovering touch, and the like.

If desired, an ultrasonic sensor may be implemented to recognize position information relating to a touch object using ultrasonic waves. The controller 180, for example, may calculate a position of a wave generation source based on information sensed by an illumination sensor and a plurality of ultrasonic sensors. Since light is much faster than ultrasonic waves, the time for which the light reaches the optical sensor is much shorter than the time for which the ultrasonic wave reaches the ultrasonic sensor. The position of the wave generation source may be calculated using this fact. For instance, the position of the wave generation source may be calculated using the time difference from the time that the ultrasonic wave reaches the sensor based on the light as a reference signal.

The camera 121 typically includes at least one a camera sensor (CCD, CMOS etc.), a photo sensor (or image sensors), and a laser sensor.

Implementing the camera 121 with a laser sensor may allow detection of a touch of a physical object with respect to a 3D stereoscopic image. The photo sensor may be laminated on, or overlapped with, the display device. The photo sensor may be configured to scan movement of the physical object in proximity to the touch screen. In more detail, the photo sensor may include photo diodes and transistors at rows and columns to scan content received at the photo sensor using an electrical signal which changes according to the quantity of applied light. Namely, the photo sensor may calculate the coordinates of the physical object according to variation of light to thus obtain position information of the physical object.

Referring now to FIGS. 1B and 1C, the mobile terminal 100 is described with reference to a bar-type terminal body. However, the mobile terminal 100 may alternatively be implemented in any of a variety of different configurations. Examples of such configurations include watch-type, clip-type, glasses-type, or as a folder-type, flip-type, slide-type, swing-type, and swivel-type in which two and more bodies are combined with each other in a relatively movable manner, and combinations thereof. Discussion herein will often relate to a particular type of mobile terminal (for example, bar-type, watch-type, glasses-type, and the like).

However, such teachings with regard to a particular type of mobile terminal will generally apply to other types of mobile terminals as well.

The mobile terminal 100 will generally include a case (for example, frame, housing, cover, and the like) forming the appearance of the terminal. In this embodiment, the case is formed using a front case 101 and a rear case 102. Various electronic components are incorporated into a space formed between the front case 101 and the rear case 102. At least one middle case may be additionally positioned between the front case 101 and the rear case 102.

The display unit 151 is shown located on the front side of the terminal body to output information. As illustrated, a window 151a of the display unit 151 may be mounted to the front case 101 to form the front surface of the terminal body together with the front case 101.

In some embodiments, electronic components may also be mounted to the rear case 102. Examples of such electronic components include a detachable battery 191, an identification module, a memory card, and the like. Rear cover 103 is shown covering the electronic components, and this cover may be detachably coupled to the rear case 102. Therefore, when the rear cover 103 is detached from the rear case 102, the electronic components mounted to the rear case 102 are externally exposed.

As illustrated, when the rear cover 103 is coupled to the rear case 102, a side surface of the rear case 102 is partially exposed. In some cases, upon the coupling, the rear case 102 may also be completely shielded by the rear cover 103. In some embodiments, the rear cover 103 may include an opening for externally exposing a camera 121b or an audio output module 152b.

The cases 101, 102, 103 may be formed by injection-molding synthetic resin or may be formed of a metal, for example, stainless steel (STS), aluminum (Al), titanium (Ti), or the like.

As an alternative to the example in which the plurality of cases form an inner space for accommodating components, the mobile terminal 100 may be configured such that one case forms the inner space. In this example, a mobile terminal 100 having a uni-body is formed in such a manner that synthetic resin or metal extends from a side surface to a rear surface.

If desired, the mobile terminal 100 may include a waterproofing unit (not shown) for preventing introduction of water into the terminal body. For example, the waterproofing unit may include a waterproofing member which is located between the window 151a and the front case 101, between the front case 101 and the rear case 102, or between the rear case 102 and the rear cover 103, to hermetically seal an inner space when those cases are coupled.

The mobile terminal includes a display unit 151, a first and a second audio output modules 151a/151b, a proximity sensor 141, an illumination sensor 142, an optical output module 154, first and second cameras 121a and 121b, first and second manipulation units 123a and 123b, a microphone 122, an interface unit 160, and the like.

It will be described for the mobile terminal as shown in FIGS. 1B and 1C. The display unit 151, the first audio output module 151a, the proximity sensor 141, an illumination sensor 142, the optical output module 154, the first camera 121a and the first manipulation unit 123a are arranged in front surface of the terminal body, the second manipulation unit 123b, the microphone 122 and interface unit 160 are arranged in side surface of the terminal body, and the second audio output modules 151b and the second camera 121b are arranged in rear surface of the terminal body.

However, it is to be understood that alternative arrangements are possible and within the teachings of the instant disclosure. Some components may be omitted or rearranged. For example, the first manipulation unit 123a may be located on another surface of the terminal body, and the second audio output module 152b may be located on the side surface of the terminal body.

The display unit 151 outputs information processed in the mobile terminal 100. The display unit 151 may be implemented using one or more suitable display devices. Examples of such suitable display devices include a liquid crystal display (LCD), a thin film transistor-liquid crystal display (TFT-LCD), an organic light emitting diode (OLED), a flexible display, a 3-dimensional (3D) display, an e-ink display, and combinations thereof.

The display unit 151 may be implemented using two display devices, which can implement the same or different display technology. For instance, a plurality of the display units 151 may be arranged on one side, either spaced apart from each other, or these devices may be integrated, or these devices may be arranged on different surfaces.

The display unit 151 may also include a touch sensor which senses a touch input received at the display unit. When a touch is input to the display unit 151, the touch sensor may be configured to sense this touch and the controller 180.

For example, may generate a control command or other signal corresponding to the touch. The content which is input in the touching manner may be a text or numerical value, or a menu item which can be indicated or designated in various modes.

The touch sensor may be configured in a form of a film having a touch pattern, disposed between the window 151a and a display on a rear surface of the window 151a, or a metal wire which is patterned directly on the rear surface of the window 151a. Alternatively, the touch sensor may be integrally formed with the display. For example, the touch sensor may be disposed on a substrate of the display or within the display.

The display unit 151 may also form a touch screen together with the touch sensor. Here, the touch screen may serve as the user input unit 123 (see FIG. 1A). Therefore, the touch screen may replace at least some of the functions of the first manipulation unit 123a.

The first audio output module 152a may be implemented in the form of a speaker to output voice audio, alarm sounds, multimedia audio reproduction, and the like.

The window 151a of the display unit 151 will typically include an aperture to permit audio generated by the first audio output module 152a to pass. One alternative is to allow audio to be released along an assembly gap between the structural bodies (for example, a gap between the window 151a and the front case 101). In this case, a hole independently formed to output audio sounds may not be seen or is otherwise hidden in terms of appearance, thereby further simplifying the appearance and manufacturing of the mobile terminal 100.

The optical output module 154 can be configured to output light for indicating an event generation. Examples of such events include a message reception, a call signal reception, a missed call, an alarm, a schedule notice, an email reception, information reception through an application, and the like. When a user has checked a generated event, the controller can control the optical output unit 154 to stop the light output.

The first camera 121a can process image frames such as still or moving images obtained by the image sensor in a capture mode or a video call mode. The processed image frames can then be displayed on the display unit 151 or stored in the memory 170.

The first and second manipulation units 123a and 123b are examples of the user input unit 123, which may be manipulated by a user to provide input to the mobile terminal 100. The first and second manipulation units 123a and 123b may also be commonly referred to as a manipulating portion, and may employ any tactile method that allows the user to perform manipulation such as touch, push, scroll, or the like. The first and second manipulation units 123a and 123b may also employ any non-tactile method that allows the user to perform manipulation such as proximity touch, hovering, or the like.

FIG. 1B illustrates the first manipulation unit 123a as a touch key, but possible alternatives include a mechanical key, a push key, a touch key, and combinations thereof

Input received at the first and second manipulation units 123a and 123b may be used in various ways. For example, the first manipulation unit 123a may be used by the user to provide an input to a menu, home key, cancel, search, or the like, and the second manipulation unit 123b may be used by the user to provide an input to control a volume level being output from the first or second audio output modules 152a or 152b, to switch to a touch recognition mode of the display unit 151, or the like.

As another example of the user input unit 123, a rear input unit (not shown) may be located on the rear surface of the terminal body. The rear input unit can be manipulated by a user to provide input to the mobile terminal 100. The input may be used in a variety of different ways. For example, the rear input unit may be used by the user to provide an input for power on/off, start, end, scroll, control volume level being output from the first or second audio output modules 152a or 152b, switch to a touch recognition mode of the display unit 151, and the like. The rear input unit may be configured to permit touch input, a push input, or combinations thereof.

The rear input unit may be located to overlap the display unit 151 of the front side in a thickness direction of the terminal body. As one example, the rear input unit may be located on an upper end portion of the rear side of the terminal body such that a user can easily manipulate it using a forefinger when the user grabs the terminal body with one hand. Alternatively, the rear input unit can be positioned at most any location of the rear side of the terminal body.

Embodiments that include the rear input unit may implement some or all of the functionality of the first manipulation unit 123a in the rear input unit. As such, in situations where the first manipulation unit 123a is omitted from the front side, the display unit 151 can have a larger screen.

As a further alternative, the mobile terminal 100 may include a finger scan sensor which scans a user's fingerprint. The controller 180 can then use fingerprint information sensed by the finger scan sensor as part of an authentication procedure. The finger scan sensor may also be installed in the display unit 151 or implemented in the user input unit 123.

The microphone 122 is shown located at an end of the mobile terminal 100, but other locations are possible. If desired, multiple microphones may be implemented, with such an arrangement permitting the receiving of stereo sounds.

The interface unit 160 may serve as a path allowing the mobile terminal 100 to interface with external devices. For example, the interface unit 160 may include one or more of a connection terminal for connecting to another device (for example, an earphone, an external speaker, or the like), a port for near field communication (for example, an Infrared Data Association (IrDA) port, a Bluetooth port, a wireless LAN port, and the like), or a power supply terminal for supplying power to the mobile terminal 100. The interface unit 160 may be implemented in the form of a socket for accommodating an external card, such as Subscriber Identification Module (SIM), User Identity Module (UIM), or a memory card for information storage.

The second camera 121b is shown located at the rear side of the terminal body and includes an image capturing direction that is substantially opposite to the image capturing direction of the first camera unit 121a.

The second camera 121b can include a plurality of lenses arranged along at least one line. The plurality of lenses may also be arranged in a matrix configuration. The cameras may be referred to as an “array camera.” When the second camera 121b is implemented as an array camera, images may be captured in various manners using the plurality of lenses and images with better qualities.

As shown in FIG. 1C, a flash 124 is shown adjacent to the second camera 121b. When an image of a subject is captured with the camera 121b, the flash 124 may illuminate the subject.

As shown in FIG. 1B, the second audio output module 152b can be located on the terminal body. The second audio output module 152b may implement stereophonic sound functions in conjunction with the first audio output module 152a, and may be also used for implementing a speaker phone mode for call communication.

At least one antenna for wireless communication may be located on the terminal body. The antenna may be installed in the terminal body or formed by the case. For example, an antenna which configures a part of the broadcast receiving module 111 may be retractable into the terminal body. Alternatively, an antenna may be formed using a film attached to an inner surface of the rear cover 103, or a case that includes a conductive material.

A power supply unit 190 for supplying power to the mobile terminal 100 may include a battery 191, which is mounted in the terminal body or detachably coupled to an outside of the terminal body.

The battery 191 may receive power via a power source cable connected to the interface unit 160. Also, the battery 191 can be recharged in a wireless manner using a wireless charger. Wireless charging may be implemented by magnetic induction or electromagnetic resonance.

The rear cover 103 is shown coupled to the rear case 102 for shielding the battery 191, to prevent separation of the battery 191, and to protect the battery 191 from an external impact or from foreign material. When the battery 191 is detachable from the terminal body, the rear case 103 may be detachably coupled to the rear case 102.

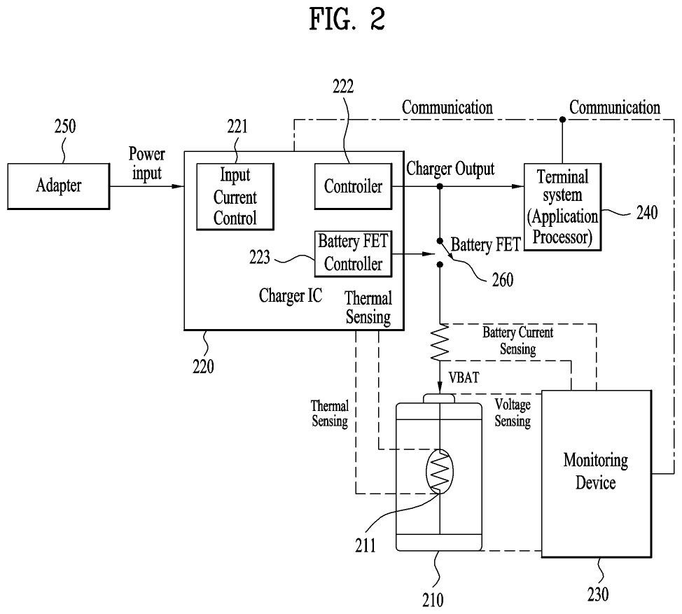

FIG. 2 is a block diagram illustrating major component blocks of an electronic device according to an embodiment of the present disclosure.

The electronic device according to an embodiment of the present disclosure may include a battery 210, a battery charger (or battery charger IC) 220, a monitoring device 230, and an application program (or application processor) 240.

The battery 210 may be a secondary battery, i.e., a device configured to store external electrical energy in a form of chemical energy and produce electricity when necessary. The secondary battery may be referred to as a rechargeable battery because it is capable of being recharged repeatedly. Secondary batteries may include, for example, Ni-based batteries and Li-based batteries.

Since the Ni-based battery has a memory phenomenon in spite of low price, it may be difficult to use the Ni-based battery for the mobile terminal 100 described above in FIG. 1A (see FIG. 1A).

Thus, the present disclosure is described based on the Li-based battery (particularly based on a Li-ion battery). However, since the present disclosure relates to adjusting a voltage applied to the secondary battery, the present disclosure is not limited to battery types.

The battery 210 of the present disclosure, which is the secondary battery, may be semi-permanently used through charge. As charge and discharge are repeated, the battery charge capacity thereof may decrease, that is, battery degradation may occur.

As a main cause of the battery degradation, a change in the battery temperature may be considered. Thus, the battery 210 may include a temperature sensor 211 configured to measure the temperature of the battery 210.

The battery charger 220 is a component configured to charge the battery 210 by applying a voltage to the battery 210.

The battery charger 220 may include an input current controller 221 configured to control a current flowing from an adapter 250 connected to a power supply, a charger output controller 222 configured to control a charge voltage, and a battery FET controller configured to control a battery FET 260 related to switching between battery charge and discharge. The battery charger 220 described herein may refer to a component configured to charge the battery 210. Accordingly, the components of the battery charger 220 may be greater or fewer than the aforementioned components except the essential components.

The monitoring device 230 may be configured to measure the voltage of the battery 210 and the current flowing due to the voltage applied to the battery 210. In some cases, the monitoring device 230 may measure the charge capacity of the battery 210, the maximum charge capacity of the battery 210, and the number of charge cycles of the battery 210.

The monitoring device 230 may be configured to measure the temperature of the battery 210 through the temperature sensor 211 disposed inside the battery 210. However, the electronic device according to the present disclosure may include a battery temperature detector (not shown) and provide the temperature to the monitoring device 230.

Since the monitoring device 230 may be configured to count the number of charge cycles and adjust the counted number of charge cycles based on a battery charge condition, which will be described later in detail, it may be desirable to detect the temperature of the battery 210 through the monitoring device 230.

The monitoring device 230 may be connected to the battery charger 220 such that the charger output controller 222 of the battery charger 220 is allowed to control the charge voltage based on measurement results of the monitoring device 230.

Herein, the number of charge cycles may not only mean the number of times that the battery 210 reaches the maximum charge capacity but also a charge rate with respect to the maximum battery charge capacity of the battery 210.

In other words, when the battery 210 reaches the maximum charge capacity from depletion, it may be regarded as one charge cycle. However, when the battery 210 reaches half of the maximum charge capacity from the depletion and reaches again the half of the maximum charge capacity from the depletion, it may be also regarded as one charge cycle.

Since the maximum charge capacity of the battery 210 may decrease depending on the use thereof, the number of charge cycles may be measured as the relative value of the charge capacity to the maximum charge capacity.

The application program 240 may refer to a program executed by the voltage applied to the battery 210. The application program 240 may correspond to all components of the electronic device that require power.

Although not shown in FIG. 2, the electronic device may further include a controller (not shown) configured to control the battery 210, the battery charger 220, and the monitoring device 230.

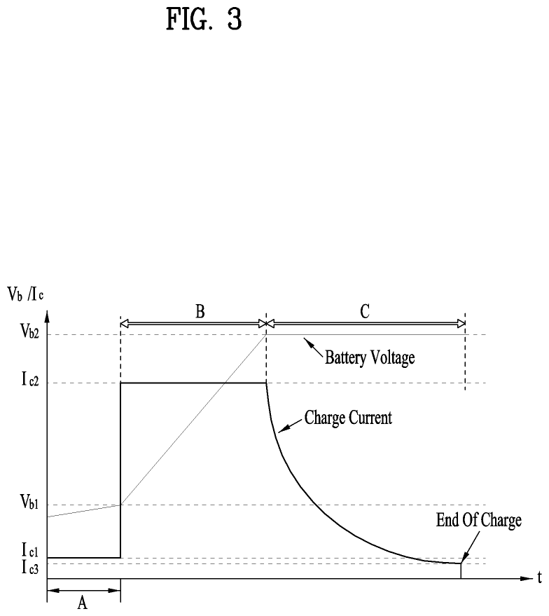

FIG. 3 is a graph showing one charge cycle of the battery 210 included in the electronic device according to an embodiment of the present disclosure.

One charge cycle of a battery may refer to a cycle for which the battery is fully charged from the full discharge.

The battery 210 of the present disclosure is the secondary battery. FIG. 3 shows a constant-current and constant-voltage charge method, which is widely used to charge secondary batteries.

Although FIG. 3 shows the constant-current and constant-voltage charge method for the Li-ion battery in consideration of that the Li-ion battery is widely used for mobile terminals, the present disclosure is applicable to other secondary batteries where the constant-current and constant-voltage charge method is used.

Referring to FIG. 3, when the Li-ion battery is attempted to be charged from the full discharge after a long period of inactivity, the Li-ion battery may not be charged because the voltage of the Li-ion battery is less than or equal to Vb1 (about 2.5 V), i.e., in a low state (section A).

Section A corresponds to a preparation period. In section A, a preparation current Ic1 (about 128 to 2048 mA) may constantly flow to increase the voltage of the Li-ion battery more than Vb1.

However, since charge and discharge are repeated in the Li-ion battery, the Li-ion battery maintains a voltage equal to or more than Vb1 when discharged so that section B may start without section A.

Section B is a constant-current charge period and may occupy most of the charge time (about 5% to 85%). Here, the constant current may be defined as a fixed current capable of quickly charging the Li-ion battery without any damages. That is, section B is a period for which a constant current Ic2 (about 500 to 3000 mA) flows constantly. When the constant current constantly flows, the voltage of the Li-ion battery may gradually increase.

Since the voltage of the Li-ion battery is relatively low, a high current may temporarily flow due to a high voltage difference between the Li-ion battery and the battery charger 220. That is, section B is a period for preventing cells of the Li-ion battery from being damaged due to the high current inflow. In section B, the constant current may be supplied to increase the voltage of the Li-ion battery gradually.

The voltage of the Li-ion battery reaches section C after passing through section B. The battery charger 220 (see FIG. 2) may stop constant-current charge and switch to constant-voltage charge mode.

Section C is a constant-voltage charge period, and the constant-voltage charge period is a period for which a voltage Vb2 equal to the full charge voltage of the Li-ion battery is maintained.

In general, Vb2 is about 3.5 to 4.4 V. In some cases, Vb2 may be 4.45 V.

In section C, the flowing charge current gradually decreases while the voltage of the Li-ion battery is constantly maintained. The Li-ion battery may be fully charged.

In section C, the voltage is constantly maintained before the full charge, and the amount of current flowing into the Li-ion battery decreases. Thus, it is possible to preventing the Li-ion battery from being damaged even when the Li-ion battery is continuously charged after fully charged.

In section C, the charge may stop when the current applied to the Li-ion battery reaches an end current Ic3, which is the full charge current of the Li-ion battery.

According to the present disclosure, the size of the constant current Ic2 and the size of the constant voltage Vb2, which may affect aging of the battery 210, may decrease based on the number of charge cycles. In this case, the number of charge cycles may be weighted based on factors affecting the battery aging.

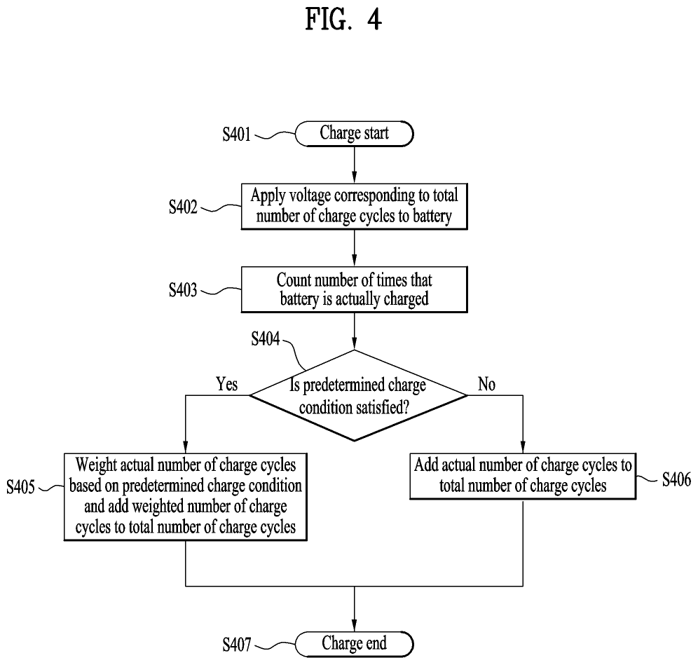

FIG. 4 is a flowchart for explaining an algorithm for preventing the aging of the battery 210 included in the electronic device according to an embodiment of the present disclosure.

According to the present disclosure, the electronic device including the rechargeable battery 210 may measure the number of charge cycles, weight the measured number of charge cycles based on the charge condition, and control the voltage applied to the battery 210 based on the weighted number of charge cycles in order to prevent aging of the battery 210.

The weighted number of charge cycles may be calculated by weighting the number of charge cycles whenever the battery 210 is charged and summing up the weighted numbers of charge cycles.

Herein, the battery charge may not only mean the full battery charge from depletion but also the number of times that the battery 210 is partially charged after power is supplied and the charge is terminated.

When the battery charge capacity increases from 40% to 60%, it may be considered that the battery 210 is charged 0.2 times. When the number of charge cycles is weighted based on the charge condition, the electronic device may calculate the number of charge cycles as 0.2+@.

In this case, if the total number of times that the number of charge cycles is weighted is more than or equal to a reference value, the electronic device may change the voltage applied to the battery 210.

When the electronic device is connected to a power supply and starts to be charged (S401), the electronic device may apply a voltage corresponding to the total number of charge cycles to the battery 210 (S402).

The total number of battery charge cycles may be stored in a memory of the electronic device and used by a processor of the electronic device when the battery 210 is charged.

In some cases, the monitoring device 230 of FIG. 2 may counts the number of charge cycles and store the total number of charge cycles.

The voltage corresponding to the total number of charge cycles may be the constant voltage Vb2 described above with reference to FIG. 3. That is, when the total number of charge cycles is more than or equal to a predetermined value, the electronic device according to the present disclosure may apply a voltage to reduce the constant voltage of the battery 210.

When the voltage is applied to the battery 210, the electronic device according to the present disclosure may count the number of times that the battery 210 is actually charged based on the applied voltage (S403). The monitoring device 230 of FIG. 2 may count the number of times that the battery 210 is actually charged.

The actual number of charge cycles may correspond to a charge rate with respect to the battery charge capacity.

However, since the charge capacity may decrease as the battery 210 ages, the monitoring device 230 may reflect the aging of the battery by measuring the battery charge capacity.

The electronic device according to the present disclosure may monitor the charge condition when the voltage is applied to the battery 210 and determine whether the monitored charge condition satisfies a predetermined condition (S404).

Specifically, the monitoring device 230 of FIG. 2 may count the number of charge cycles, monitor the current and voltage applied to the battery 210, and determine whether the current and voltage applied to the battery 210 satisfy the predetermined condition. Details thereof will be described with reference to the drawings.

The charge temperature of the battery 210 may be considered as the battery charge condition. Although FIG. 2 shows that the battery charger 220 measures the temperature, the temperature may be measured by the monitoring device 230. In some implementations, the temperature may be measured by other components. Details thereof will be described with reference to the drawings.

When the battery charge condition satisfies the predetermined condition (YES in S404), the electronic device according to the present disclosure may weight the actual number of charge cycles based on the predetermined charge condition and then add the weighted number of charge cycles to the total number of charge cycles (S405).

The electronic device according to the present disclosure may control the battery charge voltage by considering the battery charge condition (environment), instead of considering only the sum of the actual numbers of charge cycles.

When the battery charge condition does not satisfy the predetermined condition (NO in S404), the electronic device according to the present disclosure may add the actual number of charge cycles to the total number of charge cycles (S406).

In this case, whether the battery charge condition is satisfied may vary while the battery 210 is charged. For example, when the battery 210 is charged 0.5 times from the depletion, the predetermined charge condition may not be satisfied. However, when the number of charge cycles changes from 0.5 to 0.7, the predetermined charge condition may be satisfied. In this case, the electronic device according to the present disclosure may add a weight (@) to the number of charge cycles that satisfies the predetermined charge condition, 0.2 and add the number of charge cycles that does not satisfy the predetermined charge condition, 0.5 to the total number of charge cycles. That is, the electronic device according to the present disclosure may add (0.2+@)+0.5 to the total number of charge cycles.

When the number of charge cycles is added to the total number of charge cycles, the charge may be terminated (S407). Alternatively, the electronic device according to the present disclosure may add the number of charge cycles while charging the battery 201 or after completing the charge.

When the electronic device according to the present disclosure charges the battery 201 again after changing the total number of charge cycles stored in the memory or the monitoring device 230 to the total number of charge cycles where the number of charge cycles based on the battery charge is added, the electronic device according to the present disclosure may apply the voltage to the battery 201 based on the changed total number of charge cycles (S402).

The electronic device according to the present disclosure may reflect the battery charge condition in the total number of charge cycles based on the flowchart and adjust the voltage applied to the battery 201 based on the reflected battery charge condition, thereby effectively preventing the battery aging, which depends on the battery use.

The electronic device according to the present disclosure may include the battery 210 configured to be charged when the voltage is applied (see FIG. 2), the monitoring device 230 configured to monitor the charge condition of the battery 210 and the number of charge cycles of the battery 210, the battery charger 220 configured to adjust the voltage applied to the battery 210, and the controller (not shown) configured to control the battery 210, the monitoring device 230, and the battery charger 220. When the battery 210 is charged with the predetermined charge condition, the controller may be configured to control the monitoring device 230 to adjust the number of charge cycles based on the predetermined charge condition and control the battery charger 220 to apply a voltage corresponding to the adjusted number of charge cycles.

In this case, the number of charge cycles is the sum of charge rates with respect to the charge capacity of the battery 210. The controller may be configured to adjust the number of charge cycles by weighting the charge rates with respect to the charge capacity based on the predetermined charge condition.

The number of charge cycles may be regarded as accumulation of the charge rates with respect to the charge capacity of the battery 210.

Since the charge capacity may decrease depending on the battery aging, the monitoring device 230 may be configured to monitor the charge capacity of the battery 210 and the charge rates with respect to the charge capacity of the battery 210.

Hereinafter, the predetermined charge condition, which affects the battery aging, and the weight imposed based thereon will be described.

The predetermined charge condition may include a high temperature, a high voltage, and a duration thereof. However, considering that the object of the present disclosure is to reflect factors affecting the battery aging during the charge of the battery 210, the predetermined charge condition may include other battery aging factors.

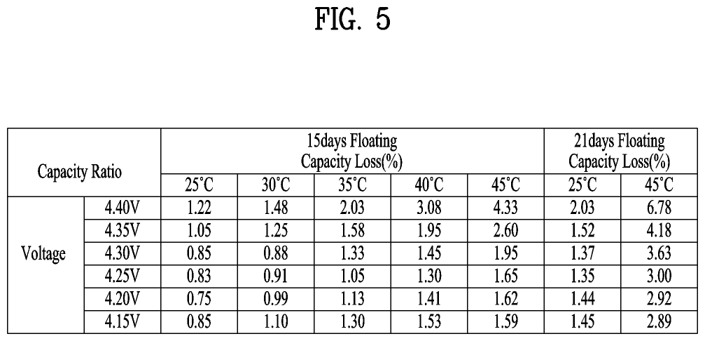

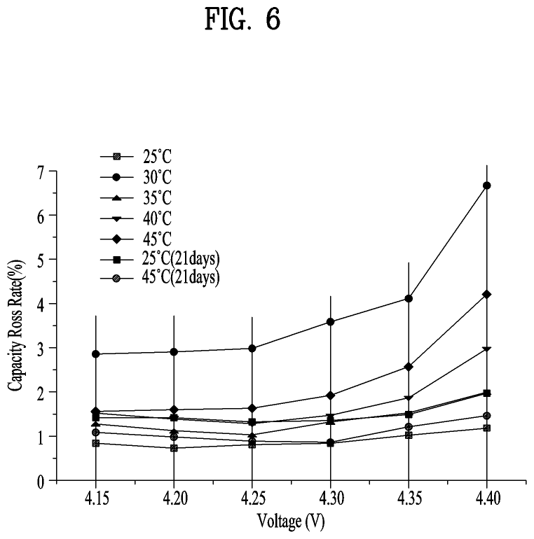

FIG. 5 is a table showing factors (e.g., high temperature, high voltage, etc.) that affect the battery aging in the electronic device according to an embodiment of the present disclosure. FIG. 6 is a graph showing the table of FIG. 5.

When the secondary battery, battery 210 is charged at a high temperature or a high voltage, it may affect the aging of the battery 210.

The table of FIG. 5 shows the percentage of decreases in a battery charge capacity based on voltages and temperatures for battery charge when a mobile terminal is floating charged for 15 and 21 days.

Referring to FIG. 6, it may be seen that the battery charge capacity significantly decreases when a battery is charged at a high temperature of 45° C. It may be seen that the battery charge capacity significantly decreases when the battery is charged with a high voltage of 4.40 V.

It may be seen that when the battery is charged at a high temperature, the charge capacity decrement increases as the battery charge voltage increases.

It may be seen that when the battery is charged at a high temperature, the battery charge capacity significantly decreases.

In other words, it may be seen that the battery charge temperature and the battery charge pressure do not act as independent factors that decrease the charge capacity.

From the comparison based on floating charge days shown in FIG. 5, it may be seen that under a condition of 25° C. and 4.40V, the charge capacity is reduced by about 1.22% when the charge is performed for 15 days. However, it may also be seen that under the same condition, the charge capacity is reduced by about 2.03% when the charge is performed for 21 days. In other words, it may be seen that the charge capacity exponentially decreases under the corresponding condition as the battery charge time increases, instead of decreasing in proportional to the battery charge time.

When the battery charge temperature is a predetermined temperature, the electronic device according to the present disclosure may control the monitoring device 230 to adjust the number of charge cycles based on the charge temperature in order to reflect the charge temperature factor that affects the battery aging.

When a time duration for which the battery 210 is at the predetermined temperature or within a certain temperature range including the predetermined temperature is a predetermined time duration, the electronic device according to the present disclosure may control the monitoring device 230 to adjust the number of charge cycles based on the charge temperature and time in order to reflect the charge temperature and time factor that affects the battery aging.

When the battery charge voltage is a predetermined voltage, the electronic device according to the present disclosure may control the monitoring device 230 to adjust the number of charge cycles based on the charge voltage in order to reflect the charge voltage factor that affects the battery aging.

[symbol]

Further, the electronic device according to the present disclosure may control the monitoring device 230 to adjust the number of charge cycles by simultaneously considering the charge voltage factor and charge temperature factor that affect the battery aging. That is, the electronic device according to the present disclosure may control the monitoring device 230 to adjust the number of charge cycles by considering weights based on a plurality of factors that affect the battery aging.

The time factor that affects the battery aging may be reflected based on a time for which the battery 210 reaches a predetermined rate with respect to the battery charge capacity

Although FIGS. 5 and 6 show floating charge data, the time for which the battery 210 reaches the predetermined rate with respect to the battery charge capacity when a user charges the electronic device may be greater than the floating charge time. Thus, the increasing time may be reflected when the number of charge cycles is adjusted based on the corresponding charge temperature or pressure.

Hereinafter, a method of adjusting the number of charge cycles will be described in detail.

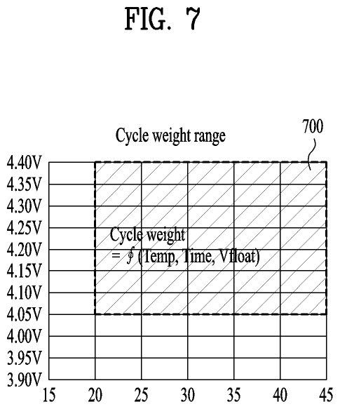

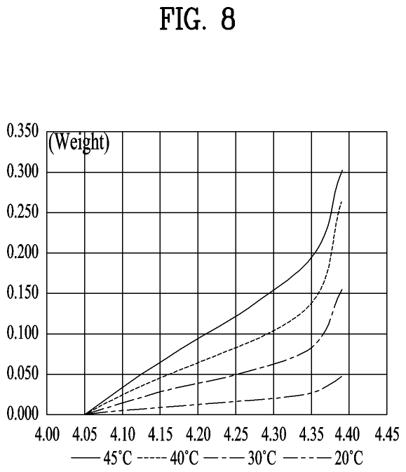

FIG. 7 is a graph showing a range in which factors that affect the battery aging are weighted in the electronic device according to an embodiment of the present disclosure, and FIG. 8 is a graph showing the weight values of FIG. 7.

FIG. 7 shows charge voltages (vertical axis) and charge temperatures (horizontal axis) as factors that affects the battery aging. In addition, FIG. 7 shows a region 700 (cycle weight) in which the number of charge cycles is weighted due to the effect on the battery aging.

Although FIG. 7 shows the region 700 in which the number of charge cycles is weighted when the battery charge voltage is more than or equal to 4.05V and less than or equal to 4.40V and the battery charge temperature is more than or equal to 20° C. and less than or equal to 45° C., the region 700 in which the number of charge cycles is weighted may be changed by repeated experiments in the range of equivalents.

The region 700 in which the number of charge cycles is weighted may be represented in three dimensions in consideration of the time factor. However, in FIG. 7, the region 700 is represented in two dimensions based on the charge voltage and charge temperature.

According to the present disclosure, the number of charge cycles may be defined as the sum of charge rates with respect to the battery charge capacity. When the battery 210 is charged with the predetermined charge condition, the controller may add weight values of FIG. 8 to the charge rates with respect to the charge capacity.

When a battery has a charge rate of 0.5 with respect to the charge capacity, a charge temperature of 30° C., and a charge voltage of 4.25V, the number of charge cycles may be adjusted by adding a weight value of 0.050 to 0.5 (alternatively, the number of charge cycles may be adjusted to 0.5(1+0.05) by adding a weight value of 0.05 to 0.5, and in this case, the weight value may be changed by repeated experiments).

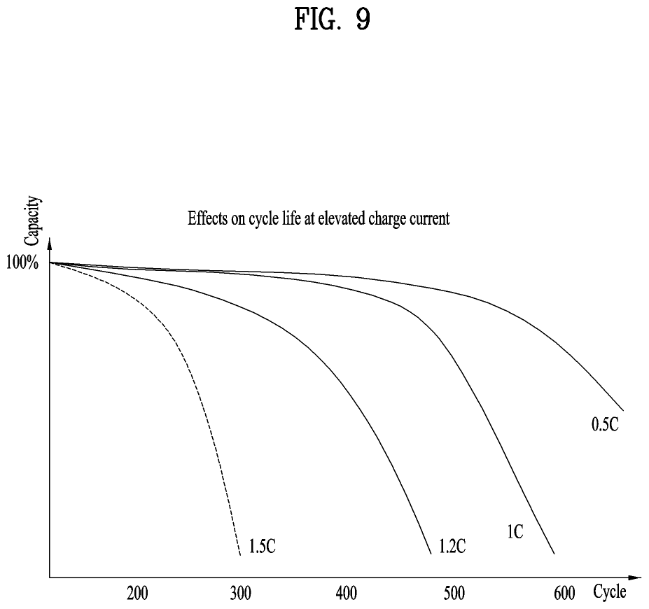

FIG. 9 is a graph showing a factor (constant current) that affects the battery aging in the electronic device according to an embodiment of the present disclosure.

The time required to fully charge the battery 210 may decrease as the current applied to the battery 210 increases, but this may reduce the life of the battery 210.

In FIG. 9 C refers to C-rate, which corresponds to the charge capacity of a charge or discharge current/battery. That is, C is a concept about how fast charge or discharge is performed, and it may correspond to the current Ic2 in the constant-current charge.

When the current is applied at 1.5 C, the charge capacity may rapidly decrease depending on the number of uses because a large current is applied to the battery 210. However, in this case, the charge speed may increase.

When the current is applied at 0.5 C, it is possible to prevent the charge capacity from decreasing depending on the number of uses because a small current is applied to the battery 210. However, in this case, the charge speed may decrease.

As shown in FIG. 9, the current amount may also affect the charge capacity of the battery. Thus, the current amount applied to the battery 210 may be weighted and considered as a factor for determining the number of charge cycles as described in FIGS. 5 and 6.

However, the current applied to the battery (particularly, the constant current described in FIG. 2) may be used as a factor variable depending on the adjusted number of charge cycles to prevent the battery aging. Details will be described later.

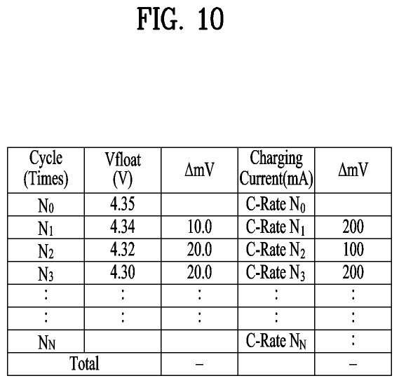

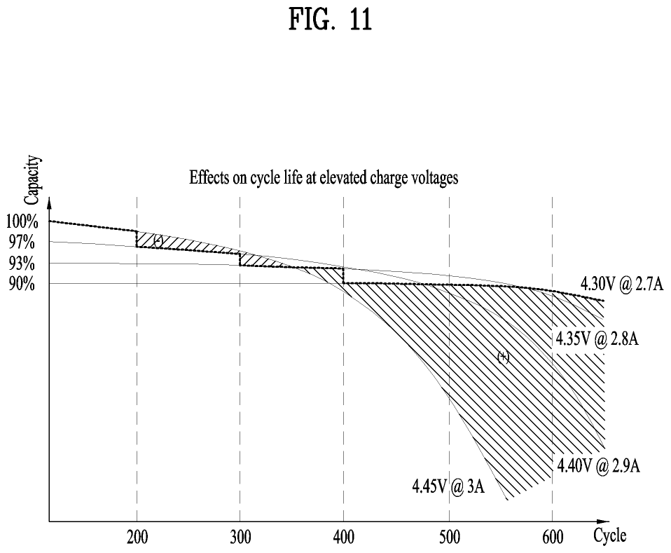

FIG. 10 is a table showing a charge algorithm for preventing the battery again in the electronic device according to an embodiment of the present disclosure, and FIG. 11 is a graph showing the charge algorithm for preventing the battery again in the electronic device according to an embodiment of the present disclosure.

In FIG. 10, Cycle may correspond to the adjusted number of charge cycles described above.

In addition, Vfloat may correspond to the charge voltage (or applied voltage) Vb2 in the constant-voltage charge described above in FIG. 2, and Vfloat is variable depending on the adjusted number of charge cycles.

Further, Charging Current may correspond to the charge current in the constant-current charge described above in FIG. 2, and Charging Current may vary depending on the adjusted number of charge cycles as in Vfloat. In FIG. 2, the concept of C-rate is used rather than Ic2 of FIG. 2 for convenience of description.

The controller included in the electronic device according to an embodiment of the present disclosure may control the battery charger 220 to perform the constant-current charge first and then perform the constant-voltage charge within one charge cycle during which the battery 210 is fully charged. When the adjusted number of charge cycles is more than a predetermined value, the controller may control the battery charger 220 to reduce the voltage applied to the battery 210 during the constant-voltage charge.

The table of FIG. 10 shows that the charge voltage decreases when the adjusted number of charge cycles increases from N₀ to N_{N}.

The reason for this is to minimize the battery degradation occurring when the voltage applied to the battery 210 increases based on the use thereof. The electronic device according to the present disclosure may adjust (reduce) the applied voltage based on the adjusted number of charge cycles rather than the actual number of charge cycles, thereby effectively coping with the battery aging.

When the adjusted number of charge cycles is more than the predetermined value, the controller included in the electronic device according to an embodiment of the present disclosure may control the battery charger 220 to reduce the current applied to the battery 210 during the constant-current charge.

The table of FIG. 10 shows that C-rate for charge decreases when the adjusted number of charge cycles increases from N₀ to N_{N}.

Similarly to voltage reduction, the reason for this is to minimize the battery degradation occurring when the current applied to the battery 210 increases based on the use thereof. The electronic device according to the present disclosure may adjust (reduce) the applied voltage based on the adjusted number of charge cycles rather than the actual number of charge cycles, thereby effectively coping with the battery aging.

Specifically, the table of FIG. 10 may correspond to the dotted line of the graph of FIG. 11. When the adjusted number of charge cycles is less than or equal to 200 cycles, the electronic device according to the present disclosure may set the constant voltage and the constant current to 4.45V and 3 A, respectively. When the adjusted number of charge cycles is more than 200 cycles and less than or equal to 300 cycles, the electronic device according to the present disclosure may set the constant voltage and the constant current to 4.40V and 2.9 A, respectively. As the adjusted number of charge cycles increases, the electronic device according to the present disclosure may gradually decrease the constant voltage and the constant current, thereby coping with the battery aging.

The battery anti-aging will be described with reference to FIG. 11. Comparing the curved line and the dotted line at 4.45V@3 A, when the adjusted number of charge cycles is less than 350 cycles, the charge capacity may decrease. When the adjusted number of charge cycles is more than or equal to 350 cycles, it is possible to prevent the charge capacity from decreasing ((+) region) enough to compensation for the decrease in the charge capacity ((+) region).

The above-described embodiments are to be construed in all aspects as illustrative and not restrictive. The scope of the disclosure should be determined by the appended claims and their legal equivalents, not by the above description, and all changes coming within the meaning and equivalency range of the appended claims are intended to be embraced therein.

What is claimed is:

1. An electronic device, comprising:
a battery configured to be charged when a voltage is applied;
a monitoring device configured to monitor a charge condition of the battery and a number of charge cycles of the battery;
a battery charger configured to adjust the voltage applied to the battery; and
a controller configured to control the battery, the monitoring device, and the battery charger,
wherein the controller is configured to:
when the battery is charged with a predetermined charge condition, control the monitoring device to adjust the number of charge cycles based on the predetermined charge condition; and
control the battery charger to apply a voltage based on the adjusted number of charge cycles to the battery.

2. The electronic device of claim 1, wherein the number of charge cycles is a sum of charge rates with respect to a charge capacity of the battery, and wherein the controller is configured to adjust the number of charge cycles by weighting the charge rates with respect to the charge capacity based on the predetermined charge condition.

3. The electronic device of claim 2, wherein the monitoring device is configured to monitor the charge capacity of the battery and the charge rates with respect to the charge capacity of the battery.

4. The electronic device of claim 1, wherein the predetermined charge condition is that a battery charge temperature corresponds to a predetermined temperature.

5. The electronic device of claim 4, wherein the predetermined charge condition is that a charge time for which the battery is charged at the predetermined temperature or within a certain temperature range including the predetermined temperature corresponds to a predetermined time.

6. The electronic device of claim 1, wherein the predetermined charge condition is that the voltage applied to the battery corresponds to a predetermined voltage.

7. The electronic device of claim 6, wherein the predetermined charge condition is that a charge time for which the battery is charged with the predetermined voltage or within a certain voltage range including the predetermined voltage corresponds to a predetermined charge time.

8. The electronic device of claim 1, wherein the monitoring device is configured to monitor at least one of a battery charge temperature, a battery charge current, or a battery charge voltage.

9. The electronic device of claim 1, wherein the controller is configured to:
control the battery charger to perform constant-current charge first and then perform constant-voltage charge within a cycle during which the battery is fully charged one time; and
when the adjusted number of charge cycles is greater than a predetermined value, control the battery charger to reduce the voltage applied to the battery during the constant-voltage charge.

10. The electronic device of claim 9, wherein when the adjusted number of charge cycles is greater than the predetermined value, the controller is configured to control the battery charger to reduce a current applied to the battery during the constant-current charge.

11. A method of controlling an electronic device, the method comprising:
monitoring a charge condition of a battery included in the electronic device and a number of charge cycles of the battery;
when the charge condition of the battery corresponds to a predetermined charge condition, adjusting the number of charge cycles based on the predetermined charge condition; and
adjusting a charge voltage applied to the battery based on the adjusted number of charge cycles.

12. The method of claim 11, wherein the number of charge cycles is a sum of charge rates with respect to a charge capacity of the battery, and the adjustment of the number of charge cycles comprises adjusting the number of charge cycles by weighting the charge rates with respect to the charge capacity based on the predetermined charge condition.
